(19) United States
(12) Patent Application Publication
(10) Pub. No.: US 2013/0153204 A1
(43) Pub. Date: Jun. 20, 2013

(54) RAM BOP SHEAR BLADE PROCESS TO ENHANCE THE TOUGHNESS

(71) Applicants: William L. CARBAUGH, Houston, TX (US); Leonard CHILDERS, Houston, TX (US); Viral SHAH, Houston, TX (US)

(72) Inventors: William L. CARBAUGH, Houston, TX (US); Leonard CHILDERS, Houston, TX (US); Viral SHAH, Houston, TX (US)

(73) Assignee: HYDRIL USA MANUFACTURING LLC, Houston, TX (US)

(21) Appl. No.: 13/331,494

(22) Filed: Dec. 20, 2011

(51) Int. Cl. E21B 29/00; C23C 16/34; E21B 33/06

(52) U.S. Cl. 166/55; 166/85.4; 427/255.394

(57) ABSTRACT

A shear ram assembly apparatus for providing the capability to shear larger diameter well casings and internal components during ram-type blowout preventer operation while requiring less force to perform the cutting. Components of the shear ram assembly apparatus, include but not limited to a plurality of hardened cutting blades that are coated with a compound that increases the hardness and reduces the coefficient of friction of the cutting blades. In this regard, a smaller force is required to perform the cutting and the cutting blades receive less wear per cut and provide greater assurance that each cut of this failsafe apparatus is successful.

### TECHNICAL FIELD

Embodiments of the subject matter disclosed herein generally relate to devices and, more particularly, to mechanisms and techniques for enhancing the toughness and improving the coefficient of friction of a shear blade for a ram-type blowout preventer (BOP).

### BACKGROUND

Blowout preventers (BOPs) are large, specialized valves for sealing, controlling and monitoring oil and gas wells. In addition to controlling the downhole pressure and flow of oil and gas, blowout preventers are intended to prevent tubing (e.g. drill pipe and well casing), tools and drilling fluid from being blown out of the wellbore when a blowout threatens. Blowout preventers are critical to the safety of the drilling crew, the drilling rig and the environment and accordingly are intended to be fail-safe devices.

A ram-type blowout preventer operates in a fashion similar to a gate valve, but uses a pair of opposing rams extending from opposite sides of the wellbore toward the center of the wellbore to restrict or prevent flow. One of four different types of ram blocks (pipe, blind, shear and blind shear) are used depending on the intended application. Specifically associated with this disclosure, shear and blind shear ram blocks have shear blades attached to the ram blocks that cut through the well casing and drill string or cut through the well casing and drill string while sealing the wellbore respectively.

As oil and gas exploration has reached greater and greater depths, oilfield tubulars have become larger in diameter and increased in wall thickness. This combination of factors has exposed problems in existing blowout preventer (BOP) design associated with shearing and sealing a wellbore in case of an emergency blowout condition. Market pressure, driven by the failure of these last line of defense devices, to solve this expensive and environmentally damaging problem has led to the desire to create a shear blade capable of reliably cutting the tubulars, and possibly well strings, associated with the oil and gas wells in use and exploration today.

Accordingly, it would be desirable to provide devices that avoid the afore-described problems and drawbacks.

### SUMMARY

According to one exemplary embodiment, there is a shear ram assembly for operation in a ram-type blowout preventer apparatus comprising a plurality of hardened cutting blades wherein the plurality of hardened cutting blades are coated with a compound for increasing the hardness and decreasing the coefficient of friction of the hardened cutting blades. Next in the exemplary embodiment, there is a plurality of blocks to which the coated plurality of cutting blades are attached or formed integrally therein.

According to another exemplary embodiment, there is a ram-type blowout preventer apparatus. Continuing with the exemplary embodiment, the ram-type blowout preventer apparatus includes a casing for enclosing the ram-type blowout preventer components, a plurality of opposing actuators connected to the casing for actuating a plurality of blocks attached to the actuators and a plurality of hardened cutting blades attached to the blocks wherein the plurality of hardened cutting blades are coated with a compound for preventing cutting surface deformation and reducing required shear force during cutting.

According to another exemplary method embodiment, there is a method for reducing the force required to shear an oilfield tubular and preventing deformation of a plurality of cutting blades associated with the ram-type blowout preventer. The exemplary method embodiment comprises applying a thin coating of a compound to the plurality of cutting blades wherein the compound comprises titanium and nitrogen. The exemplary method embodiment continues with applying the coating by a physical vapor deposition process that increases the hardness while reducing the coefficient of friction of the plurality of cutting blades.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is an exemplary embodiment of a ram-type blowout preventer shearing a tubular in a well bore;

FIG. 2 is an exemplary embodiment of a cross-section schematic view of two closing shear blades of a ram-type blowout preventer;

FIG. 3 is an exemplary embodiment exploded cutaway view of a ram-type blowout preventer shear blade with a coating applied; and

FIG. 4 is a flowchart of a method for shearing the tubulars of a wellbore with a reduced shear force and deformation of the shear blades based on an applied coating.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of ram-type blowout preventers. Ram-type blowout preventers comprise a casing, a pair of opposing cutting blades attached to ram blocks and a pair of actuators for imparting motion to the ram blocks.

Reference throughout the specification to “one embodiment” or “an embodiment” means that a particular feature, structure, or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

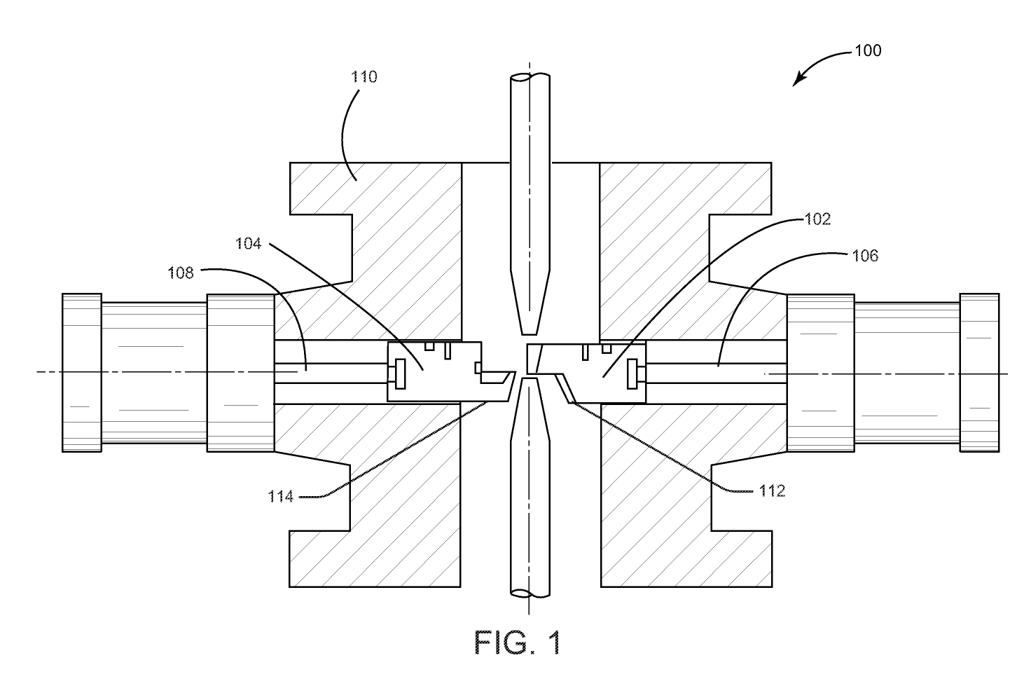

Looking to FIG. 1, an exemplary embodiment illustrates a ram-type blowout preventer 100. The exemplary embodiment ram-type blowout preventer 100 includes cutting blades 102, 104 with a coating 112, 114 and ram blocks 106, 108. In another aspect of the exemplary embodiment, a ram-type blowout preventer 100 casing 110 is illustrated and contains the components of the ram-type blowout preventer 100. Illustrated in the exemplary embodiment, the cutting blades 102, 104 have sheared the tubular 112 in the well bore 114. It should be noted that the coating illustrated at 112, 114 can be applied to the entire cutting blade 104, 106 or it can be applied to specific locations of the cutting blade. Further it should be noted that the cutting blade can be constructed of a hardened material.

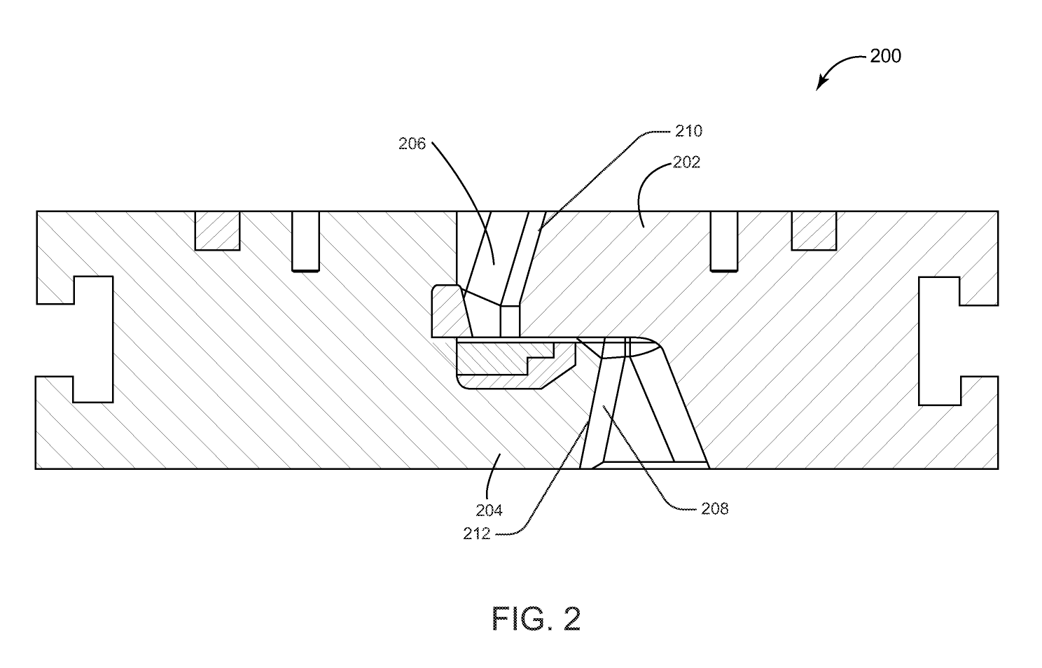

Looking now to FIG. 2, an exemplary embodiment 200 illustrates a cross section of a pair of cutting blades 202, 204 for attachment to the ram blocks of a ram-type blowout preventer. Illustrated at 206, 208 of FIG. 2 is a coating applied to contact locations 210, 212 involved in a shear cutting operation when the ram-type blowout preventer is actuated. It should be noted that the coating can be applied to the entire cutting blade based on factors such as, but not limited to, the ease of masking areas not desired for coating or to other contact areas of the cutting blade 202, 204.

An exemplary embodiment ram-type blowout preventer (BOP) has shear rams comprising a ram block or carrier and cutting blades. The exemplary embodiment cutting blades, constructed of a hardened material, are attached to the ram blocks such that the cutting blades extend, under movement of the ram blocks, from opposite sides of the well bore and meet at the center of the well bore.

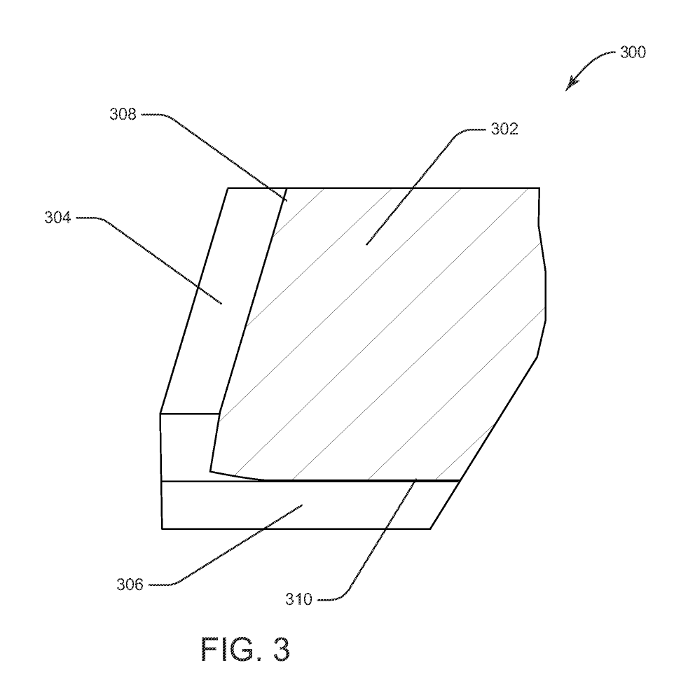

Looking now to FIG. 3, a cross section drawing of an exploded view of the end of a cutting blade 300 for a ram-type blowout preventer is illustrated. In one aspect of the exemplary embodiment, the end of the cutting blade 302 depicts a coating 304, 306 on the edge 308 and the face 310 of the cutting blade 302. It should be noted in the exemplary embodiment, that the cutting blade can be masked and coated only on these bearing surfaces or it can be coated in its entirety for ease of coating. It is noted that the cutting blade 300 shown in FIG. 3 can be configured to be attached to a corresponding ram block, for example, by screws. However, the cutting blade 300 may be in fact an integral part of the ram block if the ram block is machined with a cutting profile on the front of the block. In this way, the coating is applied directly to the cutting profile of the block as discussed later. Thus, in the following exemplary embodiments, when referring to a cutting blade it is understood a blade that can be attached to the ram block or a blade that is machined directly into the ram block.

In one aspect of the exemplary embodiment, the hardness of the cutting blades is increased and the coefficient of friction of the cutting blades is decreased by applying a coating to the cutting blades. In another aspect of the exemplary embodiment, the blade and the cutting blade (which may be a single piece) are made of hardened steel. In still another aspect of the exemplary embodiment, the coating is applied with a physical vapor deposition (PVD) process. In a further aspect of the exemplary embodiment, the coating is applied with a chemical vapor deposition (CVD) process. The exemplary embodiment process selected for applying the coating is a function of factors such as, but not limited to, the material of construction of the cutting blades, the desired properties of the coated cutting blades (i.e. hardness and coefficient of friction) and the desired coating selected for the cutting blades. In another aspect of the exemplary embodiment, the increased hardness and reduction of the coefficient of friction of the coated cutting blades prevents the cutting edge of the cutting blades from deforming during the shearing process and lowers the required shearing forces.

Continuing with the exemplary embodiment, the coating is applied to at least the top and the front face of the cutting blades but can be applied to the entire blade for ease of applying the coating. In the exemplary embodiment, ease of applying the coating refers to eliminating the need for masking areas that do not require a coating to meet the mechanical requirements of the cutting blades. Coatings associated with the exemplary embodiments comprise materials such as, but not limited to, titanium, aluminum oxide and chromium. In another aspect of the exemplary embodiment, the cutting blades are coated with compounds such as, but not limited to, titanium nitride (TiN), a glass ceramic matrix of titanium aluminum oxynitride (TiAlON), titanium carbon nitride (TiCN), etc.

Next, in an exemplary embodiment, the cutting blades of a ram-type blowout preventer are coated with a titanium nitride or a titanium aluminum oxynitride compound by a physical vapor deposition (PVD) process. The exemplary embodiment process is carried out at a temperature of approximately 300° F. and a coating, of one of the aforementioned compounds, of approximately 0.5 μm to approximately 4 μm is applied to the entire surface of the cutting blades. Continuing with the exemplary embodiment, the cutting blades are then attached to the ram blocks installed in the ram-type blowout preventer (BOP).

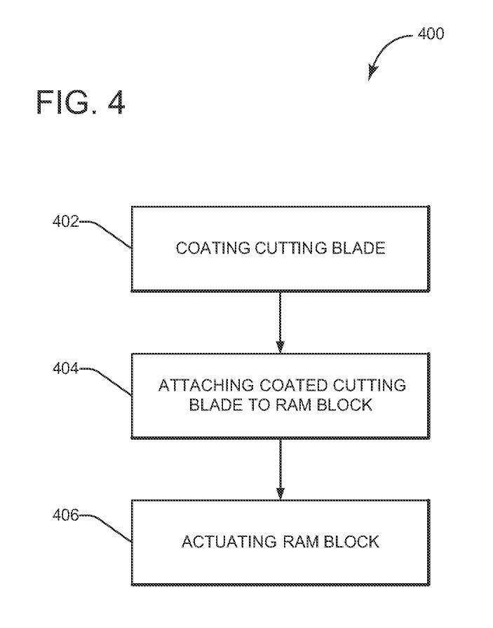

Looking now to FIG. 4, a flowchart for an exemplary method embodiment for reducing the force required shearing an oilfield tubular and preventing deformation of the cutting blades associated with a ram-type blowout preventer is depicted. Beginning at step 402 of the exemplary method embodiment, a cutting blade is coated with a previously described compound by either of the physical vapor deposition or chemical vapor deposition processes. In the exemplary embodiment, the cutting blade can be masked such that the coating is applied only to bearing surfaces or the cutting blades can be completely coated.

Continuing at exemplary method embodiment step 404, the coated cutting blade is attached to a ram block associated with the ram-type blowout preventer. It should be noted that more than one cutting blade, and correspondingly more than one ram block, can be associated with a single ram-type blowout preventer.

Next, at exemplary method embodiment step 406, the ram blocks are actuated which drives the coated cutting blades together shearing the oilfield tubular. Depending on the operation of the ram-type blowout preventer, the cutting blades can remain in the actuated position as a seal for the wellbore or they can be retracted allowing the remaining tubular above the cutting blades to be retracted.

The disclosed exemplary embodiments provide a device and a method for coating the cutting blades of a ram-type blowout preventer and integrating the coated cutting blades into the ram-type blowout preventer. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements to those recited in the literal languages of the claims.

What is claimed is:

1. A shear ram assembly apparatus for operation in a ram-type blowout preventer, said apparatus comprising:
a hardened cutting blade wherein said hardened cutting blade is coated with a compound for preventing cutting surface deformation and reducing required shear force during cutting; and
a ram block having said coated hardened cutting blade.

2. The apparatus of claim 1, wherein said coating is applied with a physical vapor deposition (PVD) process.

3. The apparatus of claim 1, wherein said coating is applied with a chemical vapor deposition (CVD) process.

4. The apparatus of claim 1, wherein said coating prevents cutting surface deformation during cutting by increasing hardness of said cutting edge.

5. The apparatus of claim 1, wherein said coating reduces required shear force during cutting by decreasing said cutting surface coefficient of friction.

6. The apparatus of claim 2, wherein said coating is applied at a temperature of approximately 300° F.

7. The apparatus of claim 2, wherein said compound comprises titanium and nitrogen.

8. The apparatus of claim 7, wherein said compound is titanium nitride (TiN).

9. The apparatus of claim 7, wherein said compound is a glass ceramic matrix of titanium aluminum oxynitride (TiAlON).

10. The apparatus of claim 7, wherein said compound is titanium carbon nitride (TiCN).

11. The apparatus of claim 1, wherein said coated hardened cutting blade is either attached to the ram block or integrally formed with the ram block.

12. A ram-type blowout preventer (BOP) comprising:
a casing for enclosing said ram-type blowout preventer components;
a plurality of opposing actuators connected to said casing for actuating a plurality of ram blocks attached to said actuators;
a hardened cutting blade for each of said plurality of ram blocks, wherein said hardened cutting blade is coated with a compound for preventing cutting surface deformation and reducing required shear force during cutting.

13. The apparatus of claim 12, wherein said coating is applied with a physical vapor deposition (PVD) process.

14. The apparatus of claim 12, wherein said coating prevents cutting surface deformation during cutting by increasing hardness of said cutting edge.

15. The apparatus of claim 12, wherein said coating reduces required shear force during cutting by decreasing said cutting surface coefficient of friction.

16. The apparatus of claim 13, wherein said coating is applied at a temperature of approximately 300° F.

17. The apparatus of claim 13, wherein said compound comprises titanium and nitrogen.

18. The apparatus of claim 17, wherein said compound is titanium nitride (TiN).

19. The apparatus of claim 17, wherein said compound is a glass ceramic matrix of titanium aluminum oxynitride (TiAlON).

20. The apparatus of claim 12, wherein said coated hardened cutting blade is either attached to a corresponding ram block or integrally formed with the corresponding ram block.

21. A method for reducing the force required to shear an oilfield tubular and preventing deformation of a cutting blade associated with said ram-type blowout preventer (BOP), said method comprising:
applying a thin coating of a compound to said cutting blade wherein said compound comprises titanium and nitrogen; and
using a physical vapor deposition process to apply the coating to increase the hardness and reduce the coefficient of friction of said cutting blades.
